(19) United States
(12) Patent Application Publication
(10) Pub. No.: US 2015/0248060 A1
(43) Pub. Date: Sep. 3, 2015

(54) METHOD OF MAKING THERMAL INSULATION FILM AND THERMAL INSULATION FILM PRODUCT

(71) Applicant: Konica Minolta Laboratory U.S.A., Inc., San Mateo, CA (US)

(72) Inventor: Jun Amano, Hillsborough, CA (US)

(21) Appl. No.: 14/627,505

(22) Filed: Feb. 20, 2015

Related U.S. Application Data
(60) Provisional application No. 61/946,432, filed on Feb. 28, 2014.

(51) Int. Cl. G03F 7/20; G03F 7/30

(52) U.S. Cl. CPC G03F 7/2002; G03F 7/30; G03F 7/2004

(57) ABSTRACT

A method that includes coating a photopolymer layer on a substrate to create a photopolymer coating, passing light from a light source through an aperture array to create a light interference pattern, and exposing the photopolymer coating to the light interference pattern to create cross-linked regions and non-cross-linked regions within the photopolymer coating. The method further includes creating a thermal insulation film product by dissolving the non-cross-linked regions to create a porous thermal insulation film disposed on the substrate.

### CROSS-REFERENCE TO RELATED APPLICATIONS

This application is a non-provisional patent application of U.S. Provisional Patent Application Ser. No. 61/946,432, filed on Feb. 28, 2014, and entitled: “Method of Making Thermal Insulation Film and Thermal Insulation File Product.” Accordingly, this non-provisional patent application claims priority to U.S. Provisional Patent Application Ser. No. 61/946,432 under 35 U.S.C. §119(e). U.S. Provisional Patent Application Ser. No. 61/946,432 is hereby incorporated in its entirety.

### BACKGROUND

Buildings consume approximately 68% of all electricity in the United States.

According to a 2006 study by the United States Department of Energy, 30% of a building's energy is lost through inefficient windows. In order to achieve energy savings year-round, an energy-saving window featuring a high degree of thermal insulation coupled with solar heat rejection, e.g., the rejection of infra-red light, is desired. However, retrofitting existing buildings with state of the art energy efficient widows is a costly proposition, especially in buildings that were originally constructed using single pane glass windows. Furthermore, existing window films require multiple coatings in addition to double or triple pane designs.

Highly efficient thermal insulation films with good transparency and flexibility are desired for low cost retrofits and other uses, such as for vehicle windows, window tinting/coloration, etc.

### SUMMARY OF INVENTION

In general, in one aspect, embodiments of the invention related to a method that includes coating a photopolymer layer on a substrate to create a photopolymer coating, passing light from a light source through an aperture array to create a light interference pattern, and exposing the photopolymer coating to the light interference pattern to create cross-linked regions and non-cross-linked regions within the photopolymer coating. The method further includes creating a thermal insulation film product by dissolving the non-cross-linked regions to create a porous thermal insulation film disposed on the substrate.

In general, in another aspect, embodiments of the invention related to a thermal insulation film product that includes a polymer substrate, and a thermal insulation film disposed on the polymer substrate. The thermal insulation film is formed by using a light interference pattern to selectively cross-link a photopolymer coating on the polymer substrate

Other aspects of the invention will be apparent from the following description and the appended claims.

### BRIEF DESCRIPTION OF DRAWINGS

FIG. 1 shows a system for making insulation films in accordance with one or more embodiments of the invention.

FIG. 2 shows a flow chart for a method of making thermal insulation film products in accordance with one or more embodiments of the invention.

FIG. 3 demonstrates different aperture array patterns in accordance with one or more embodiments of the invention.

FIG. 4 shows a light interference pattern created by interference from an aperture array in accordance with one or more embodiments of the invention.

FIGS. 5A and 5B show thermal insulation film products in accordance with one or more embodiments.

### DETAILED DESCRIPTION

Specific embodiments of the invention will now be described in detail with reference to the accompanying figures. Like elements in the various figures are denoted by like reference numerals for consistency.

In the following detailed description of embodiments of the invention, numerous specific details are set forth in order to provide a more thorough understanding of the method for making a thermal insulation film and a thermal insulation film product. However, it will be apparent to one of ordinary skill in the art that the invention may be practiced without these specific details. In other instances, well-known features have not been described in detail to avoid unnecessarily complicating the description.

In general, embodiments of the invention include a method for producing a thermal insulation film and a thermal insulation film product. In accordance with one or more embodiments, the method may be used to create highly porous, flexible, and semi-transparent films using a coherent or semi-coherent light source, without the need for a complex photomask. In accordance with one or more embodiments, the method may produce highly porous, e.g., a relative porosity of >99%, flexible, and semi-transparent coatings with very high thermal insulation properties by employing a photolithographic technique utilizing a photopolymer coating and a semi-coherent light source and/or laser. In one example of the method, mesh-like structures of cross-linked polymer are formed within a photopolymer layer by exposing the photopolymer layer to a structured pattern of light. In one or more embodiments of the invention, the structured pattern of light is an interference pattern created by the interference of multiple sources of light.

In accordance with one or more embodiments, a photopolymer layer disposed on the surface of a transparent substrate material layer is exposed to a light interference pattern. During the exposure of the photopolymer layer, self-focussing and self-trapping of the light instigates polymerization to create connected mesh-like structures of cross-linked polymer inside the photopolymer layer. After the exposure of the light, any non-cross-linked regions within the photopolymer layer may be dissolved using an etching process, as known in the art. After etching, a highly flexible semi-transparent porous layer remains disposed on the surface of the transparent substrate material layer thereby forming a thermal insulation film product.

In accordance with one or more embodiments, the thermal insulation film product may be used as a thermal insulation layer for any number of transparent structures. For example, a thermal insulation film product may be installed on an existing single pane window to increase the thermal insulation properties of the window. Furthermore, a thermal insulation film product may include additional layers, such as one or more additional films that are disposed on top of the porous thermal insulation layer to block the transmission of heat (infra-red light) through the film. In other embodiments, the nature of the mesh-like structures of cross-linked polymer may be tailored to give the porous layer a particular optical response to allow for the apparent color of the thermal insulation film product to be tuned. The optical and thermal properties of the thermal insulation layer may be engineered by changing the nature of the mesh-like structures of cross-linked polymer. In addition, known additional films may be employed in combination with the flexible thermal insulation film.

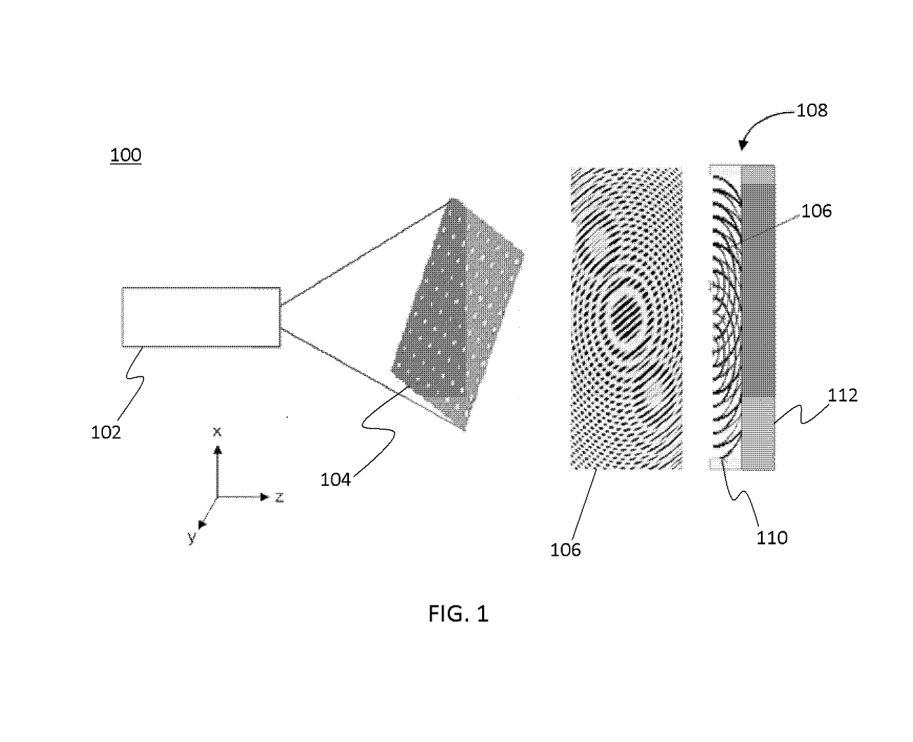

FIG. 1 shows a system (100) for making insulation films in accordance with one or more embodiments. The system includes light source (102), an aperture array (104), and a sample (108). In order to expose the photopolymer layer (110) to the light from the light source (102), and thereby create the mesh-like structures of cross-linked polymer, the light from the light source (102) passes through the aperture array (104). The aperture array (104) functions to split the light from light source (102) into an array of light sources that each appear to emit the light. As the light from the aperture array (104) of the light source (102) propagates, an interference pattern (106) is created. Different interference patterns (106) may be engineered through the use of different types or patterns of the aperture array (104) in accordance with one or more embodiments of the invention.

In accordance with one or more embodiments, when the interference pattern (106), which includes a number of alternating high intensity and low intensity light regions, is projected onto the photopolymer layer (110) of the sample (108), a cross-linked mesh structure is created through polymerization within the photopolymer layer (110) of the substrate (112). In accordance with one or more embodiments, the shape and structure of the cross-linked mesh structure may be engineered by positioning the aperture array (104) in the x, y, or z directions.

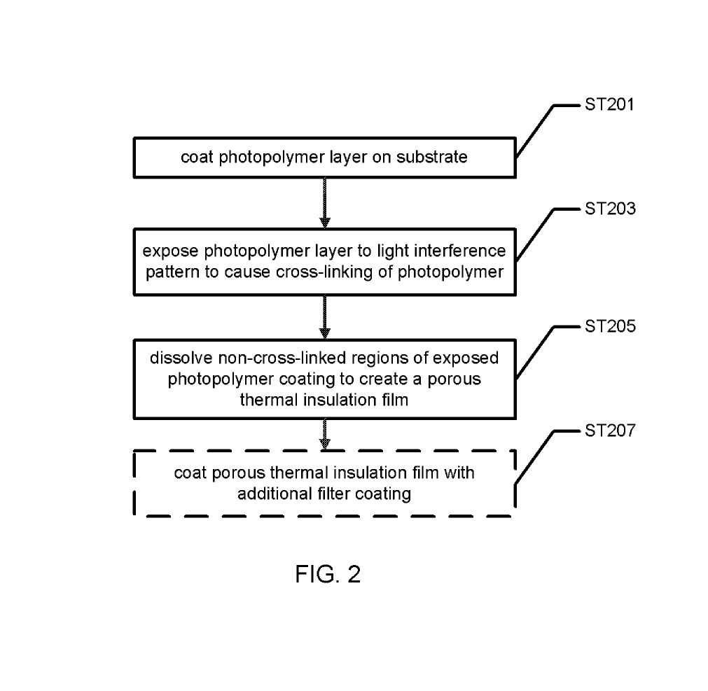

FIG. 2 shows a flow chart for a method of making a thermal insulation film product in accordance with one more embodiments of the invention. The method shown in FIG. 2 may be used in conjunction with the system described above in reference to FIG. 1. In step 201, a substrate layer may be coated with a photopolymer layer according to known techniques, for example spin coating. In accordance with one or more embodiments, the substrate may be a transparent polymer layer and the photopolymer layer may be a photosensitive polymer layer disposed on a surface of the substrate. In step 203, the photosensitive polymer layer is exposed to a light interference pattern to photo-induced cross-linking of the photopolymer layer.

After exposure, the regions of non-cross-linked photopolymer are removed in step 205. In accordance with one or more embodiments, the exposed photopolymer may be subjected to a solvent bath to dissolve the non-cross-linked photopolymer regions while preserving the cross-linked polymer regions. Accordingly, dissolving the non-cross-linked photopolymer regions creates a porous thermal insulting film disposed on the substrate layer. Optionally, in step 207 an additional layer may be formed directly on the porous thermal insulting film layer in accordance with one or more embodiments of the invention. For example, an IR blocking film or other optical film, antireflective or reflective coatings, notch filter coatings, or other stop-band or pass-band optical filter coatings may be employed without departing from the scope of the present invention.

Coherent or semi-coherent light sources may be used as the light source (102) in accordance with one or more embodiments. For example, a semi-coherent UV light emitting diode (LED) may be used and/or a UV laser diode may be used. The light source may be a single LED, array of LEDs, single diode laser, laser diode array without departing from the scope of the present invention. Furthermore, while UV light sources and UV sensitive photopolymers are discussed herein as examples, other wavelengths of light may be used and appropriately coupled with photopolymers having the corresponding sensitivities without departing from the scope of the present invention. In accordance with one or more embodiments of the invention, the light source, array pattern and position of the aperture array, as well as the specific photopolymers used are selected in conjunction based on the properties desired in the insulating layer.

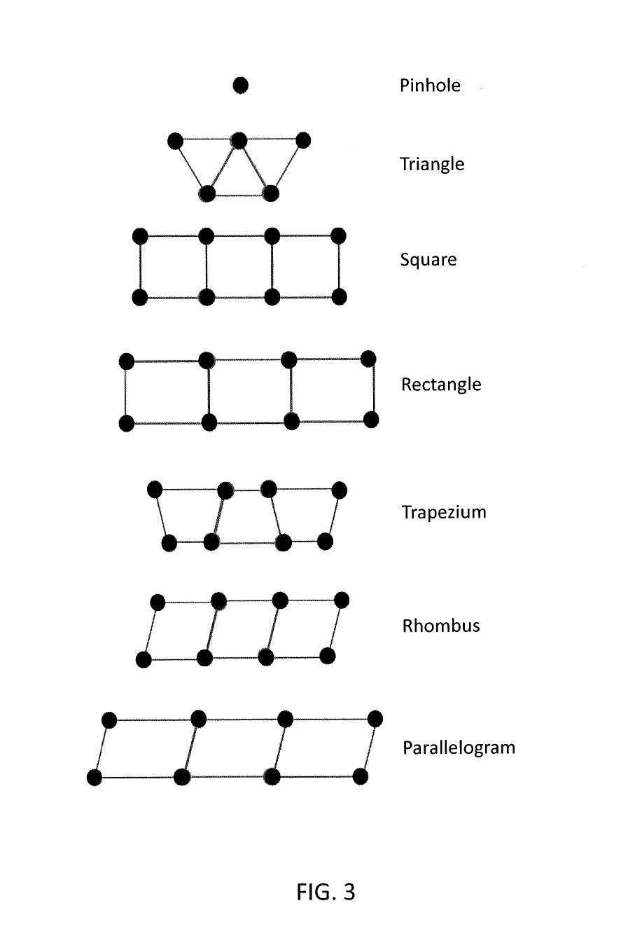

In accordance with one or more embodiments of the invention, the interference pattern may be generated by passing the light from the light source through an aperture array. The interference pattern (106) shown in FIG. 1 is for illustration only. Any number of different types of interference patterns may be employed without departing from the scope of the present invention. FIG. 3 demonstrates different aperture array patterns in accordance with one or more embodiments of the invention. For example, a triangular array, a square array, a rectangular array, a rhombus array, a parallelogram array, a trapezium array, or any other arrangement of apertures may be used without departing from the scope of the present invention. Passing light from a light source through such an array of pinholes effectively creates multiple light sources that subsequently overlap and cause an interference pattern to be created. The strength of the interference pattern may depend of the degree of coherence of the initial light source. However, a perfectly coherent light source is not necessary to implement one or more embodiments of the invention and partially coherent sources such as LEDs may be used.

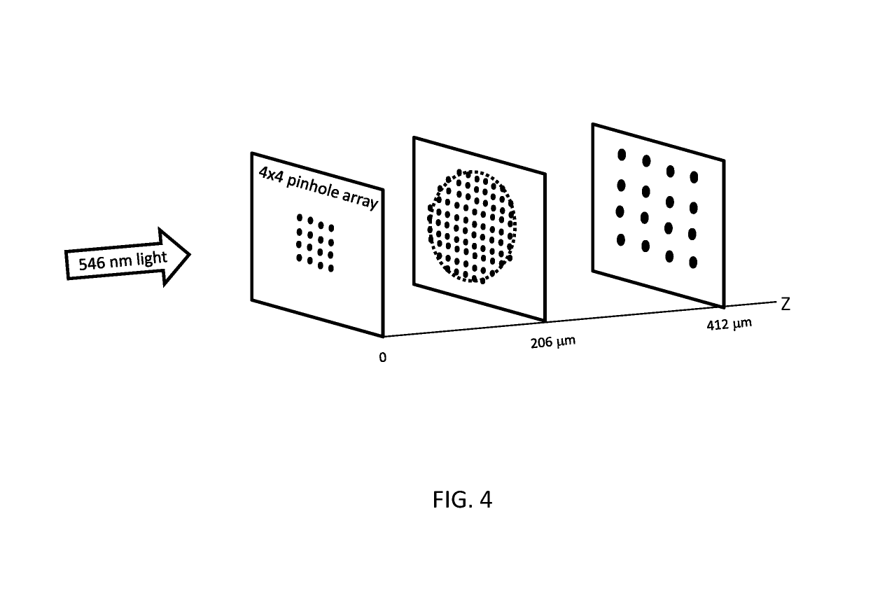

The interference pattern (106) may be three dimensional in nature. FIG. 4 shows a light interference pattern created by interference from an aperture array in accordance with one or more embodiments of the invention. In the example shown in FIG. 4, the pinhole diameters are 1.2 μm and the periodic distance between pinholes is 15 μm and the interference pattern is shown for light having a wavelength of 546 nm. Such an interference pattern may result in maximum intensity regions that are enhanced by a factor of N²/4, where N is the number of pinholes (apertures) in the array. Furthermore, along the propagation direction of the light, a number of constructive multi-beam interferences appear in different planes, a phenomena known as the Talbot effect. In the example shown in FIG. 4, a 4×4 pinhole array is used with the interference pattern in several different planes shown at increasing distances from the array (z=0, 206 μm, and 412 μm). Planes with best contrast are referred to as Talbot planes, localized at focal distances z=LTalbot, where LTalbot=(1/q)(d2/λ). In this equation, q is an integer, d is the periodicity of the pinholes and λ is the wavelength of light. In this example, the q=2 Talbot plane is localized at 412 μm. More information regarding the interference patterns created by pinhole arrays and the resulting Talbot effect can be found in “Sensitive measurement of partial coherence using a pinhole array” by P. Petruck, R. Riesenberg, and R. Kowarschik, (SENSOR+TEST Conference 2009—OPTO 2009 Proceedings, p. 35), incorporated herein by reference in its entirety. Therefore, one or ordinary skill in the art will appreciate that the distance between the aperture array (104) and the sample (108) is determined based on the desired interference pattern in accordance with one or more embodiments of the invention.

In accordance with one or more embodiments, the photopolymer layer (110) is disposed on the surface of a transparent substrate polymer layer substrate (112). The formulation of the photopolymer layer (110) may include photoinitiators and monomers/oligomers that are dispersed in a binder matrix. As used herein, the term photointiator is used to refer to chemicals that form energetic radical species when exposed to light of a certain wavelength. Examples of photoinitiators include, but are not limited to, 1-hydroxy-cyclohexyphenyi-ketone and benzophenone. Other photoinitiators may also be used without departing from the scope of the present invention.

In accordance with one or more embodiments, the monomers/oligomers that are mixed with the photoinitiators in the photopolymer layer (110) may be various types of acrylate monomers and oligomers. These monomers and oligomers interact with the radicals formed from the photoinitiators to form cross-linked polymers. Examples of acrylate monomers and oligomers include, but are not limited to, epoxy acrylate, aliphatic urethane acrylate, aromatic urethane acrylate, polyester acrylate, acrylic acrylate, polyether acrylates, bisphenol A epoxy acrylate, isobonyl acetate, 1,6-diacetoxyhexane, and di(trimehtylolpropane) tetraacrylate. One of ordinary skill in the art will appreciate that other monomers and oligomers may also be used without departing from the scope of the present invention. Furthermore, examples of binders used in the photopolymer layer (110) include, but are not limited to, polyvinyl alcohol (PVA), polymethyl methacrylate (PMMA), polyacrylie acid (PAA), and ployvinyl chloride (PVC). Other binders may also be used without departing from the scope of the present invention.

In accordance with one or more embodiments, the density of the cross-linked polymers may be dependent on the combined density of the photointiators and monomers/oligomers in the binder matrix and the intensity of irradiating UV light from the interference pattern (106). Furthermore, the typical refractive index of cross-linked polymers is higher than those of non cross-linked monomers/oligomers. For example, the typical refractive index of acylate monomers and oligomers is about 1.5 and the refractive index of the cross-linked polymer may be 10-20% higher than the non cross linked polymer. Accordingly, during exposure, the high intensity light caused by constructive interference of the light from the aperture array within the photopolymer layer (110) may cause a refractive index increase within these regions. Consequently, light entering these regions may undergo self-focusing and/or self-trapping. The self-focusing and/or self-trapping phenomena may create numerous columns of propagating light that are trapped inside the cross-linked polymer regions and propagate through the high refractive index polymer regions. These numerous columns of propogating light may lead to cross-linking of the photopolmer layer (110), thereby forming a complex mesh structure within the photopolymer layer (110). After exposure and cross-linking of the photopolymer layer (110), the non cross-linked monomer regions may be dissolved by solvant such as acetone, toluene, and other solvents in which the unreacted monomer is soluble. A resulting film product that is a highly porous mesh structure is thereby formed after dissolving the non cross-linked monomer/oligomer regions.

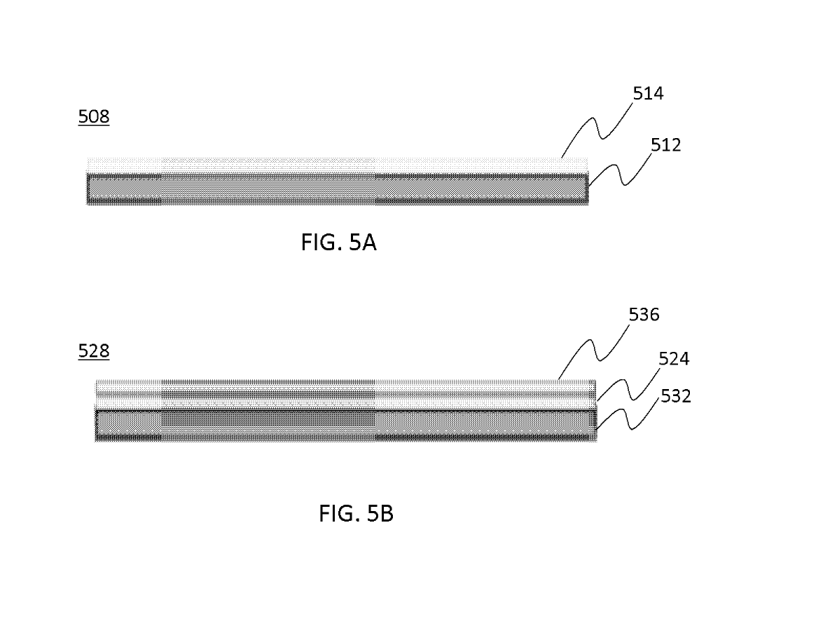

FIGS. 5A and 5B show two examples of insulation film products or devices in accordance with one or more embodiments. FIG. 5A shows one example of a stand-alone insulation film product (508) in accordance with one or more embodiments. The stand-alone insulation film product (508) includes a transparent polymer substrate (512), e.g., formed from a low cost polymer such as polyethylene terephthalate (PET) or polyethylene naphthalate (PEN). Disposed and/or bonded on a surface of the transparent polymer substrate (512) is a highly porous thermal insulation film (514) in accordance with one or more embodiments of the invention. FIG. 5B shows another example of an insulation film product (528) that includes a highly porous thermal insulation film (524) sandwiched between a transparent polymer substrate (532) and one or more additional layers (536). The one or more additional layers (536) may be optical filter layers, for example, an IR-cut film for blocking infra-red radiation, or the like. The one or more additional layers may also include adhesive layers or the like to facilitate the installation of such a product.

In accordance with one or more embodiments, the size (length, width, and surface area) of the thermal insulation film products may be chosen in accordance with the desired application. For example, the thermal insulation film product may be suitable for use as a retrofit film that will be installed on an preexisting window.

In addition, one or more embodiments of the invention may be used in a roll-to-roll process in conjunction with the embodiments disclosed in FIG. 2.

Embodiments of the invention may advantageously provide for a highly efficient thermal insulation film with good transparency and flexibility for low cost retrofits and other uses, such as vehicle windows, window tinting/coloration, etc.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

What is claimed is:

1. A method, comprising:
coating a photopolymer layer on a substrate to create a photopolymer coating;
passing light from a light source through an aperture array to create a light interference pattern;
exposing the photopolymer coating to the light interference pattern to create cross-linked regions and non cross-linked regions within the photopolymer coating; and
creating a thermal insulation film product by dissolving the non cross-linked regions to create a porous thermal insulation film disposed on the substrate.

2. The method of claim 1, wherein the substrate is a polymer substrate.

3. The method of claim 2, wherein the polymer substrate comprises one selected from a group consisting of PET and PEN.

4. The method of claim 1, wherein the aperture array is a two-dimensional (2D) array and comprises a plurality of uniformly spaced apertures.

5. The method of claim 4, wherein each of the plurality of uniformly spaced apertures is a circle and the 2D array is spatially arranged as one selected from a group consisting of a triangular array, a square array, a rectangular array, a rhombus array, a parallelogram array, and a trapezium array.

6. The method of claim 1, wherein the light source is a UV light source.

7. The method of claim 6, wherein the UV light source is one selected from a group consisting of a LTV laser and a UV light emitting diode (LED).

8. The method of claim 1, wherein the photopolymer layer comprises a photoinitiator and a binder.

9. The method of claim 8, wherein the photopolymer layer further comprises at least one selected from a group consisting of a monomer and an oligomer.

10. The method of claim 9, wherein the photoinitiator is one selected from a group consisting of 1-hydroxy-cyclohexyphenyi-ketone and benzophenone.

11. The method of claim 9, wherein the monomer or oligomer is one selected from a group consisting of epoxy acrylate, aliphatic urethane acrylate, aromatic urethane acrylate, polyester acrylate, and acrylic acrylate.

12. The method of claim 9, wherein the binder is one selected from a group consisting of polyvinyl alcohol (PVA), polymethyl methacrylate (PMMA), polyacrylie acid (PAA), and ployvinyl chloride (PVC).

13. A thermal insulation film product comprising:
a polymer substrate; and
a thermal insulation film disposed on the polymer substrate,
wherein the thermal insulation film is formed by using a light interference pattern to selectively cross-link a photopolymer coating on the polymer substrate.

14. The thermal insulation film product of claim 13, further comprising a filter coating disposed on the thermal insulation film.

15. The thermal insulation film product of claim 13, wherein the thermal insulation film has a thickness of 50-550 microns.

16. The thermal insulation film product of claim 15, wherein the porosity of the thermal insulation film exceeds 99%.

17. The thermal insulation film product of claim 13, wherein the polymer substrate comprises a transparent polymer material.

18. The thermal insulation film product of claim 17, wherein the transparent polymer material comprises one selected from a group consisting of PET and PEN.

19. The thermal insulation film product of claim 13, wherein the thermal insulation film comprises at least one selected from a group consisting of cross-linked epoxy acrylate, cross-linked aliphatic urethane acrylate, cross-linked aromatic urethane acrylate, cross-linked polyester acrylate, and cross-linked acrylic acrylate.

20. The thermal insulation film product of claim 14, wherein the filter coating is an infrared cut film.
